(19) United States
(12) Patent Application Publication
(10) Pub. No.: US 2020/0020679 A1
(43) Pub. Date: Jan. 16, 2020

(54) Semiconductor Device and Method for Forming the Semiconductor Device

(71) Applicant: Sanken Electric Co., Ltd., Niiza-Shi (JP)

(72) Inventors: Hiroshi SHIKAUCHI, Niiza-Shi (JP); Satoru WASHIYA, Niiza-Shi (JP); Yuki TANAKA, Niiza-Shi (JP); Ning WEI, Niiza-Shi (JP)

(73) Assignee: Sanken Electric Co., Ltd., Niiza-Shi, Saitama (JP)

(21) Appl. No.: 16/030,946

(22) Filed: Jul. 10, 2018

(51) Int. Cl. H01L 27/02; H01L 29/45; H01L 29/16; H01L 21/82; H01L 29/78; H01L 29/47; H01L 27/06

(52) U.S. Cl. CPC H01L 27/0211; H01L 29/45; H01L 29/1608; H01L 27/0255; H01L 29/7806; H01L 29/47; H01L 27/0605; H01L 21/8213

(57) ABSTRACT

A semiconductor device and a method for forming the semiconductor device. The semiconductor device includes: a unipolar component at least including a first epitaxial layer and a first substrate; and a bypass component at least including a second epitaxial layer and a second substrate; the unipolar component and the bypass component are connected in parallel; a difference of a thickness of the unipolar component and a thickness of the bypass component is lower than or equal to a predetermined value.

### TECHNICAL FIELD

Embodiments of the present disclosure generally relate to the field of semiconductor, and more particularly, to a semiconductor device and a method for forming the semiconductor device.

### BACKGROUND

In order to provide a semiconductor device having high reliability and capable of reducing increase in on-resistance, a unipolar compound semiconductor element is connected to a bypass semiconductor element in parallel.

FIG. 1 is a diagram which shows a schematic illustration of the unipolar compound semiconductor element 101 and the bypass semiconductor element 102 in the prior art. As shown in FIG. 1, the unipolar compound semiconductor element 101 is connected to the bypass semiconductor element 102 though external lines “L”.

Reference document 1: US2013/0069082A1

This section introduces aspects that may facilitate a better understanding of the disclosure. Accordingly, the statements of this section are to be read in this light and are not to be understood as admissions about what is in the prior art or what is not in the prior art.

### SUMMARY

However, the inventor found that the unipolar compound semiconductor element 101 and the bypass semiconductor element 102 are separately configured and connected via external lines, in some cases, the amount of heat generated by the two components are different such that there exists a heat transfer which results an unstable operation.

In order to solve at least part of the above problems, methods, apparatus, devices are provided in the present disclosure. Features and advantages of embodiments of the present disclosure will also be understood from the following description of specific embodiments when read in conjunction with the accompanying drawings, which illustrate, by way of example, the principles of embodiments of the present disclosure.

In general, embodiments of the present disclosure provide a semiconductor device and a method for forming the semiconductor device. It is expected to decrease or avoid the heat transfer between the unipolar compound semiconductor element and the bypass semiconductor element.

In a first aspect, a semiconductor device is provided, includes: a unipolar component at least including a first epitaxial layer and a first substrate; and a bypass component at least including a second epitaxial layer and a second substrate; the unipolar component and the bypass component are connected in parallel; a difference of a thickness of the unipolar component and a thickness of the bypass component is lower than or equal to a predetermined value.

In one embodiment, the unipolar component and the bypass component include silicon carbide material.

In one embodiment, a difference of a first thickness and a second thickness is lower than or equal to 10% and higher than or equal to −10%; the first thickness is an addition of the thickness of the first epitaxial layer and the thickness of the first substrate, the second thickness is an addition of the thickness of the second epitaxial layer and the thickness of the second substrate.

In one embodiment, a difference of a first concentration and a second concentration is lower than or equal to 10% and higher than or equal to −10%; the first concentration is a concentration of carriers in the first epitaxial layer, the second concentration is a concentration of carriers in the second epitaxial layer.

In one embodiment, a source electrode of the unipolar component is an aluminum silicon type element; and a barrier metal of the bypass component is a titanium or molybdenum type element.

In a second aspect, a method for forming a semiconductor device is provided, includes: providing a unipolar component at least comprising a first epitaxial layer and a first substrate; and providing a bypass component at least comprising a second epitaxial layer and a second substrate; the unipolar component and the bypass component are connected in parallel; a difference of a thickness of the unipolar component and a thickness of the bypass component is lower than or equal to a predetermined value.

According to various embodiments of the present disclosure, a difference of a thickness of the unipolar component and a thickness of the bypass component is lower than or equal to a predetermined value. Therefore, the amount of heat generated by the unipolar component is the same as (or almost same as) the amount of heat generated by the bypass component due to the same thickness (or almost the same thickness), such that the heat transfer between the unipolar component and the bypass component can be decreased or avoided.

### BRIEF DESCRIPTION OF THE DRAWINGS

The above and other aspects, features, and benefits of various embodiments of the disclosure will become more fully apparent, by way of example, from the following detailed description with reference to the accompanying drawings, in which like reference numerals or letters are used to designate like or equivalent elements. The drawings are illustrated for facilitating better understanding of the embodiments of the disclosure and not necessarily drawn to scale, in which:

FIG. 1 is a diagram which shows a schematic illustration of the unipolar compound semiconductor element 101 and the bypass semiconductor element 102 in the prior art;

FIG. 2 is a diagram which shows a schematic illustration of a semiconductor device 200 in accordance with an embodiment of the present disclosure;

FIG. 3 is a diagram which shows a method for forming a semiconductor device in accordance with an embodiment of the present disclosure.

### DETAILED DESCRIPTION

The present disclosure will now be described with reference to several example embodiments. It should be understood that these embodiments are discussed only for the purpose of enabling those skilled persons in the art to better understand and thus implement the present disclosure, rather than suggesting any limitations on the scope of the present disclosure.

It should be understood that when an element is referred to as being “connected” or “coupled” or “contacted” to another element, it may be directly connected or coupled or contacted to the other element or intervening elements may be present. In contrast, when an element is referred to as being “directly connected” or “directly coupled” or “directly contacted” to another element, there are no intervening elements present. Other words used to describe the relationship between elements should be interpreted in a like fashion (e.g., “between” versus “directly between”, “adjacent” versus “directly adjacent”, etc.).

As used herein, the terms “first” and “second” refer to different elements. The singular forms “a” and “an” are intended to include the plural forms as well, unless the context clearly indicates otherwise. The terms “comprises,” “comprising,” “has,” “having,” “includes” and/or “including” as used herein, specify the presence of stated features, elements, and/or components and the like, but do not preclude the presence or addition of one or more other features, elements, components and/or combinations thereof.

The term “based on” is to be read as “based at least in part on”. The term “cover” is to be read as “at least in part cover”. The term “one embodiment” and “an embodiment” are to be read as “at least one embodiment”. The term “another embodiment” is to be read as “at least one other embodiment”. Other definitions, explicit and implicit, may be included below.

In this disclosure, unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

### A First Aspect of Embodiments

A semiconductor device is provided in the embodiments.

FIG. 2 is a diagram which shows a schematic illustration of a semiconductor device 200 in accordance with an embodiment of the present disclosure. As shown in FIG. 2, the semiconductor device 200 includes: a unipolar component 201 at least including a first epitaxial layer 2011 and a first substrate 2012; and a bypass component 202 at least including a second epitaxial layer 2021 and a second substrate 2022.

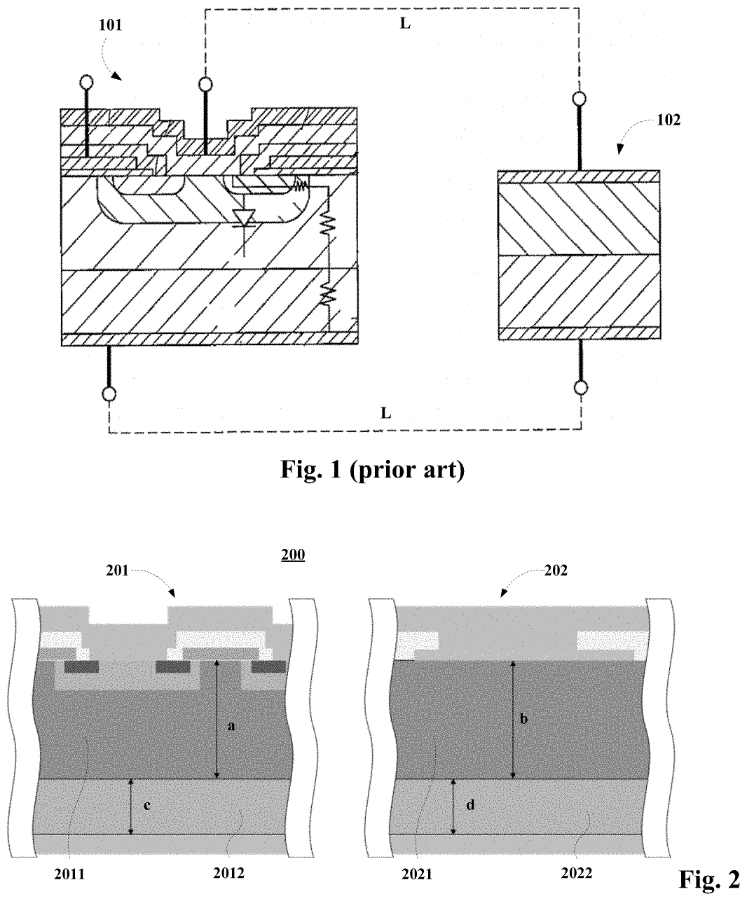

The unipolar component 201 and the bypass component 202 are connected in parallel. For example, the unipolar component 201 may be connected to the bypass component 202 though external lines “L”, as shown in FIG. 1. Alternatively, the unipolar component 201 may be connected to the bypass component 202 via a conductive pattern.

In this disclosure, a difference of a thickness of the unipolar component 201 and a thickness of the bypass component 202 is lower than or equal to a predetermined value. The predetermined value may be an absolute value, such as T mm, or may be a relative value, such as X % (percentage); and it is not limited thereto.

In this disclosure, the unipolar component and the bypass component include silicon carbide (SiC) material. The unipolar component 201 may be a MOSFET (Metal Oxide Semiconductor Field Effect Transistor) element, the bypass component 202 may be an SBD (Schottky Barrier Diode) element; and it is not limited thereto.

For example, the unipolar component 201 is a SiC-MOSFET and the bypass component 202 is a SiC-SBD.

Therefore, the amount of heat generated by the unipolar component is the same as (or almost same as) the amount of heat generated by the bypass component due to the same thickness (or almost the same thickness), such that the heat transfer between the unipolar component and the bypass component can be decreased or avoided.

In an embodiment, a difference of a first thickness and a second thickness is lower than or equal to 10% and higher than or equal to −10%; the first thickness is an addition of the thickness of the first epitaxial layer and the thickness of the first substrate, the second thickness is an addition of the thickness of the second epitaxial layer and the thickness of the second substrate.

As shown in FIG. 2, “a” is the thickness of the first epitaxial layer 2011 and “c” is the thickness of the first substrate 2012; “b” is the thickness of the second epitaxial layer 2021 and “d” is the thickness of the second substrate 2022. For example, the difference of a+c and b+d is within ±10%.

Therefore, the heat transfer between the unipolar component and the bypass component can be further decreased or avoided.

In an embodiment, a difference of a first concentration and a second concentration is lower than or equal to 10% and higher than or equal to −10%; the first concentration is a concentration of carriers in the first epitaxial layer, the second concentration is a concentration of carriers in the second epitaxial layer.

For example, H1 is the concentration of carriers in the first epitaxial layer 2011 and H2 is the concentration of carriers in the second epitaxial layer 2021, the difference of H1 and H2 is within ±10%.

Therefore, the heat transfer between the unipolar component and the bypass component can be further decreased or avoided.

It should be appreciated that the epitaxial layer may include a drift layer and/or an active layer, and so on; but it is not limited thereto. For example, the epitaxial layer may include N− type drift layer and/or N+ type drift layer. Furthermore, the concentration of carriers in the epitaxial layer may be caused by n-doping, some related art can be used for reference.

In an embodiment, a source electrode of the unipolar component is an aluminum silicon (Al—Si) type element and a barrier metal (such as Schottky metal) of the bypass component is a titanium (Ti) or molybdenum (Mo) type element.

Therefore, the heat transfer between the unipolar component and the bypass component can be further decreased or avoided.

It should be appreciated that some components or elements are illustrated as examples in FIG. 2. However, it is not limited thereto, for example, connections or positions of the components or elements may be adjusted, and/or, some components or elements may be omitted. Moreover, some components or elements not shown in FIG. 2 may be added, while components or elements shown in FIG. 2 but not explained can be referred in the relevant art.

It is to be understood that, the above examples or embodiments are discussed for illustration, rather than limitation. Those skilled in the art would appreciate that there may be many other embodiments or examples within the scope of the present disclosure.

As can be seen from the above embodiments, a difference of a thickness of the unipolar component and a thickness of the bypass component is lower than or equal to a predetermined value. Therefore, the amount of heat generated by the unipolar component is the same as (or almost same as) the amount of heat generated by the bypass component due to the same thickness (or almost the same thickness), such that the heat transfer between the unipolar component and the bypass component can be decreased or avoided.

### A Second Aspect of Embodiments

A method for forming a semiconductor device is provided in the embodiments. The semiconductor device is illustrated in the first aspect of embodiments, and the same contents as those in the first aspect of embodiments are omitted.

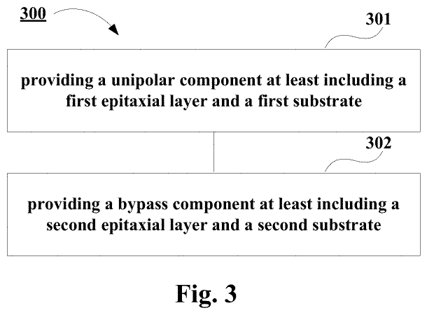

FIG. 3 is a diagram which shows a method for forming a semiconductor device in accordance with an embodiment of the present disclosure. As shown in FIG. 3, the method 300 includes:

Block 301, providing a unipolar component at least including a first epitaxial layer and a first substrate;

Block 302, providing a bypass component at least including a second epitaxial layer and a second substrate; the unipolar component and the bypass component are connected in parallel; a difference of a thickness of the unipolar component and a thickness of the bypass component is lower than or equal to a predetermined value.

It should be appreciated that FIG. 3 is only an example of the disclosure, but it is not limited thereto. For example, the order of operations at blocks or steps may be adjusted, and/or, some blocks or steps may be omitted. Moreover, some blocks or steps not shown in FIG. 3 may be added.

In an embodiment, the unipolar component and the bypass component include silicon carbide material.

In an embodiment, a difference of a first thickness and a second thickness is lower than or equal to 10% and higher than or equal to −10%; the first thickness is an addition of the thickness of the first epitaxial layer and the thickness of the first substrate, the second thickness is an addition of the thickness of the second epitaxial layer and the thickness of the second substrate.

In an embodiment, a difference of a first concentration and a second concentration is lower than or equal to 10% and higher than or equal to −10%; the first concentration is a concentration of carriers in the first epitaxial layer, the second concentration is a concentration of carriers in the second epitaxial layer.

In an embodiment, a source electrode of the unipolar component is an aluminum silicon type element and a barrier metal of the bypass component is a titanium or molybdenum type element.

As can be seen from the above embodiments, a difference of a thickness of the unipolar component and a thickness of the bypass component is lower than or equal to a predetermined value. Therefore, the amount of heat generated by the unipolar component is the same as (or almost same as) the amount of heat generated by the bypass component due to the same thickness (or almost the same thickness), such that the heat transfer between the unipolar component and the bypass component can be decreased or avoided.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and integrated circuits (ICs) with minimal experimentation.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device.

While various aspects of embodiments of the present disclosure are illustrated and described as block diagrams, flowcharts, or using some other pictorial representation, it will be appreciated that the blocks, apparatus, systems, techniques or methods described herein may be implemented in, as non-limiting examples, hardware, software, firmware, special purpose circuits or logic, general purpose hardware or controller or other computing devices, or some combination thereof.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous.

Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in language specific to structural features and/or methodological acts, it is to be understood that the present disclosure defined in the appended claims is not necessarily limited to the specific features or acts described above. Rather, the specific features and acts described above are disclosed as example forms of implementing the claims.

1. A semiconductor device, comprising:
a unipolar component at least comprising a first epitaxial layer and a first substrate, wherein a source electrode of the unipolar component is an aluminum silicon type element; and
a bypass component at least comprising a second epitaxial layer and a second substrate, wherein a barrier metal of the bypass component is a titanium or molybdenum type element; the unipolar component and the bypass component are connected in parallel;
wherein a difference of a first thickness and a second thickness is lower than or equal to 10% and higher than or equal to −10%;
the first thickness is an addition of the thickness of the first epitaxial layer and the thickness of the first substrate, the second thickness is an addition of the thickness of the second epitaxial layer and the thickness of the second substrate.

2. The semiconductor device according to claim 1, wherein the unipolar component and the bypass component comprise silicon carbide material.

3. (canceled)

4. The semiconductor device according to claim 1, wherein a difference of a first concentration and a second concentration is lower than or equal to 10% and higher than or equal to −10%;
the first concentration is a concentration of carriers in the first epitaxial layer, and the second concentration is a concentration of carriers in the second epitaxial layer.

5. (canceled)

6. A method for forming a semiconductor device, comprising:
providing a unipolar component at least comprising a first epitaxial layer and a first substrate, wherein a source electrode of the unipolar component is an aluminum silicon type element; and
providing a bypass component at least comprising a second epitaxial layer and a second substrate, wherein a barrier metal of the bypass component is a titanium or molybdenum type element; the unipolar component and the bypass component are connected in parallel;
wherein a difference of a first thickness and a second thickness is lower than or equal to 10% and higher than or equal to −10%;
the first thickness is an addition of the thickness of the first epitaxial layer and the thickness of the first substrate, the second thickness is an addition of the thickness of the second epitaxial layer and the thickness of the second substrate.

7. The method according to claim 6, wherein the unipolar component and the bypass component comprise silicon carbide material.

8. (canceled)

9. The method according to claim 6, wherein a difference of a first concentration and a second concentration is lower than or equal to 10% and higher than or equal to −10%;
the first concentration is a concentration of carriers in the first epitaxial layer, and the second concentration is a concentration of carriers in the second epitaxial layer.

10. (canceled)
